(19) United States
(12) Patent Application Publication
(10) Pub. No.: US 2026/0182250 A1
(43) Pub. Date: Jun. 25, 2026

(54) THERMOELECTRIC MODULE

(71) Applicant: LINTEC Corporation, Tokyo (JP)

(72) Inventor: Kazuhiro KIKUCHI, Tokyo (JP)

(73) Assignee: LINTEC Corporation, Tokyo (JP)

(21) Appl. No.: 19/414,428

(22) Filed: Dec. 10, 2025

(30) Foreign Application Priority Data
Dec. 20, 2024 (JP) 2024-225519

(51) Int. Cl. H10N 19/00; H10N 10/82

(52) U.S. Cl. CPC H10N 19/101; H10N 10/82

(57) ABSTRACT

There is provided a thermoelectric module including: a first substrate having a first main surface; a second substrate having a second main surface arranged to face the first main surface; a plurality of thermoelectric elements arranged between the first main surface and the second main surface; and an electrode arranged on the first main surface and connected to a first thermoelectric element and a second thermoelectric element among the plurality of thermoelectric elements. An insulating layer including a first portion and a second portion is arranged on the first main surface, the first portion being arranged to surround the electrode and to be spaced apart from the electrode, the second portion being arranged between the first thermoelectric element and the second thermoelectric element.

### CROSS-REFERENCE TO RELATED APPLICATION(S)

This application claims priority to and the benefit of Japanese Patent Application No. 2024-225519, filed on Dec. 20, 2024, the entire disclosure of which is incorporated herein by reference.

### BACKGROUND OF THE INVENTION

### Field of the Invention

The present invention relates to a thermoelectric module.

### Description of the Related Art

A thermoelectric module using the Seebeck effect or the Peltier effect is known. As such a thermoelectric module, use of a so-called π-type thermoelectric conversion element is known. The π-type thermoelectric conversion element is configured by providing a pair of electrodes provided on a substrate in a manner that the pair of electrodes are mutually spaced apart, providing a P-type thermoelectric element on one electrode of the pair of electrodes, and an N-type thermoelectric element on the other electrode of the pair of electrodes, and connecting the upper surfaces of the P-type and N-type thermoelectric elements to a common electrode provided on an opposing substrate. In production of such a thermoelectric module, a P-type thermoelectric element and an N-type thermoelectric element are bonded to electrodes provided on a substrate via a bonding material. In a case where a solder material or the like is used as the bonding material, the molten solder may flow due to surface tension or the like at the time of bonding by heating such as reflow, which may cause displacement of a thermoelectric element. In a case where the thermoelectric element is displaced, a defect may occur: for example, a short circuit occurs due to contact of the thermoelectric element with an adjacent electrode. Japanese Patent Laid-Open No. 2022-157777 discloses that a wall structure is arranged on an electrode to surround a thermoelectric element, thereby suppressing displacement of the thermoelectric element.

### SUMMARY OF THE INVENTION

To improve performance of a thermoelectric module, it is desired to improve a mounting density of thermoelectric elements arranged on a substrate.

An object of the present invention is to provide a technique advantageous in improving performance of the thermoelectric module.

In view of the above issue, a thermoelectric module according to an embodiment of the present invention includes: a first substrate having a first main surface; a second substrate having a second main surface arranged to face the first main surface; a plurality of thermoelectric elements arranged between the first main surface and the second main surface; and an electrode arranged on the first main surface and connected to a first thermoelectric element and a second thermoelectric element among the plurality of thermoelectric elements, wherein an insulating layer including a first portion and a second portion is arranged on the first main surface, the first portion being arranged to surround the electrode and to be spaced apart from the electrode, the second portion being arranged between the first thermoelectric element and the second thermoelectric element.

### BRIEF DESCRIPTION OF THE DRAWINGS

FIG. 1 is a perspective view illustrating a configuration example of a thermoelectric module according to a present embodiment.

FIGS. 2A and 2B are diagrams each illustrating improvement of a mounting density of the thermoelectric module of FIG. 1.

FIGS. 3A to 3D are diagrams each illustrating an arrangement example of an insulating layer of the thermoelectric module of FIG. 1.

FIGS. 4A and 4B are diagrams each illustrating an arrangement example of the insulating layer of the thermoelectric module of FIG. 1.

FIGS. 5A to 5E are diagrams each illustrating a shape example of an electrode of the thermoelectric module of FIG. 1.

FIGS. 6A to 6C are diagrams each illustrating an arrangement example of the insulating layer of the thermoelectric module of FIG. 1.

FIGS. 7A and 7B are diagrams each illustrating a modified example of the thermoelectric module of FIG. 1.

### DESCRIPTION OF THE EMBODIMENTS

Hereinafter, embodiments will be described in detail with reference to the attached drawings. Note, the following embodiments are not intended to limit the scope of the claimed invention, and limitation is not made to an invention that requires a combination of all features described in the embodiments. Two or more of the multiple features described in the embodiments may be combined as appropriate. Furthermore, the same reference numerals are given to the same or similar configurations, and redundant description thereof is omitted.

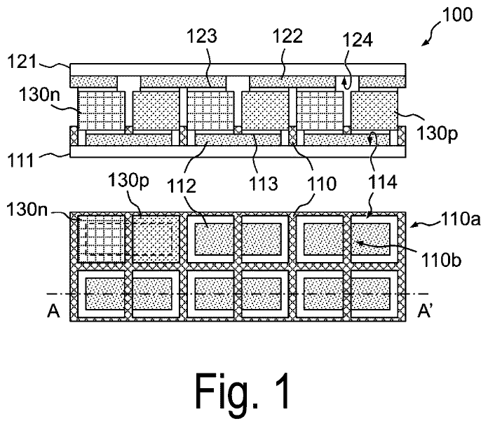

A thermoelectric module 100 according to an embodiment of the present disclosure will be described with reference to FIGS. 1 to 7B. FIG. 1 is a diagram illustrating a configuration example of the thermoelectric module 100 according to the present embodiment. A cross section of the thermoelectric module 100 is illustrated on the upper side of FIG. 1. A plan view focusing on an arrangement example of electrodes 112 and an insulating layer 110 on a substrate 111 of the thermoelectric module 100 is illustrated on the lower side of FIG. 1. The cross-sectional view on the upper side illustrates a cross section taken along line A-A′ of the plan view on the lower side. In the plan view on the lower side, illustration of thermoelectric elements 130 other than two thermoelectric elements on the upper left is omitted to focus on the arrangement of the electrodes 112 and the insulating layer 110.

The thermoelectric module 100 includes the substrate 111 having a main surface 114, a substrate 121 having a main surface 124 arranged so as to face the main surface 114 of the substrate 111, and a plurality of thermoelectric elements 130 arranged between the main surface 114 of the substrate 111 and the main surface 124 of the substrate 121. A plurality of electrodes 112 are arranged on the main surface 114 of the substrate 111. Two thermoelectric elements 130 are connected to one electrode 112 via a bonding material 113 using a solder material or the like. The thermoelectric elements 130 connected to one electrode 112 may be an N-type thermoelectric element 130n and a P-type thermoelectric element 130p having conductivity types different from each other as illustrated in FIG. 1. Similarly, a plurality of electrodes 122 are arranged on the main surface 124 of the substrate 121. Two thermoelectric elements 130 are connected to one electrode 122 via a bonding material 123 using a solder material or the like. The thermoelectric elements 130 connected to one electrode 112 may be an N-type thermoelectric element 130n and a P-type thermoelectric element 130p having conductivity types different from each other as illustrated in FIG. 1. The thermoelectric module 100 illustrated in FIG. 1 has a structure of a so-called π-type thermoelectric conversion element, and the N-type thermoelectric element 130n and the P-type thermoelectric element 130p are alternately connected in series.

When the thermoelectric module 100 is produced, the thermoelectric elements 130 are bonded onto the electrode 112 via the bonding material 123 using a solder material or the like. When the thermoelectric elements 130 and the electrode 112 are bonded by heating such as reflow, the molten solder may flow due to surface tension or the like, which may cause displacement of the thermoelectric elements 130. When the thermoelectric elements 130 come into contact with an electrode 112 different from the electrode 112 to be bonded in design due to the displacement of the thermoelectric elements 130, characteristics of the thermoelectric module 100 may be deteriorated due to a short circuit. Accordingly, in the thermoelectric module 100 of the present embodiment, the insulating layer 110 including a portion 110a arranged so as to surround each of the electrodes 112 and to be spaced apart from the electrode 112 and a portion 110b arranged between two thermoelectric elements 130 connected to one electrode 112 is arranged on the main surface 114 of the substrate 111. With the insulating layer 110 arranged, the displacement of the thermoelectric elements 130 due to the flow of the molten solder during reflow is suppressed.

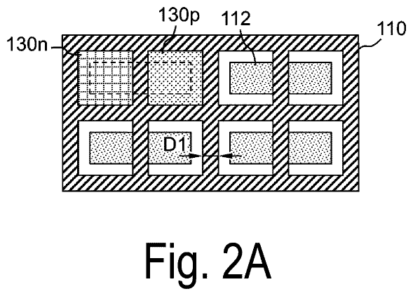

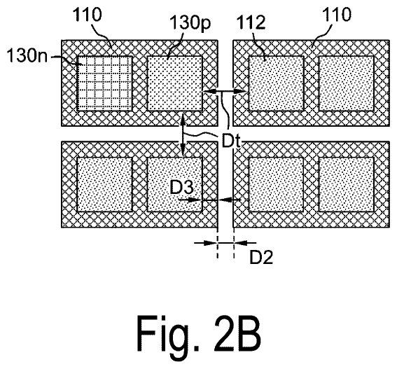

Next, an advantage of the configuration in which the portion 110a of the insulating layer 110 arranged to surround each of the electrodes 112 is arranged to be spaced apart from the electrode 112 will be described with reference to FIGS. 2A and 2B. FIG. 2A illustrates the arrangement of the electrodes 112 and the insulating layer 110 in the thermoelectric module 100 of the present embodiment. FIG. 2B illustrates the arrangement of electrodes 112 and an insulating layer 110 in a thermoelectric module of a comparative example. In the thermoelectric module of the comparative example, the insulating layer 110 is arranged on the electrodes 112. Although the entire insulating layer 110 is arranged on each of the electrodes 112 in FIG. 2B, the insulating layer 110 may be also arranged between the electrodes 112.

In the configurations illustrated in FIGS. 2A and 2B, thermoelectric elements 130 of the same size are arranged (illustrated in the upper left of each drawing). That is, sizes of openings for arranging the thermoelectric elements 130 provided in the insulating layer 110 are the same. Let a length D1 be a minimum formation width of the insulating layer 110. Further, in the thermoelectric module of the comparative example, let a length D2 be a minimum distance between the electrodes 112 necessary for processing when forming the electrodes 112. In the thermoelectric module of the comparative example, let a length D3 be a formation width of the insulating layer 110 on each of the electrodes 112 in consideration of formation accuracy and displacement of the insulating layer 110 when the insulating layer 110 is formed on the electrode 112.

As illustrated in FIG. 2A, in the thermoelectric module 100 of the present embodiment, the thermoelectric elements 130 are arranged at intervals of the length D1 in an up-down direction and a left-right direction. On the other hand, in the thermoelectric module of the comparative example illustrated in FIG. 2B, an interval between the adjacent thermoelectric elements 130 connected to the electrodes 112 is a length Dt=D2+D3×2 in both the up-down direction and the left-right direction. The length D3, which is the formation width on the electrode 112, may be set to be greater than or equal to the length D1 (D1≤D3) in consideration of the formation accuracy, displacement, and the like when the insulating layer 110 is formed on the electrode 112. Thus, the relationship between the length D1, which is the interval at which the thermoelectric elements 130 are arranged in the thermoelectric module 100 of the present embodiment, and the length Dt, which is the interval at which the thermoelectric elements 130 are arranged in the thermoelectric module of the comparative example, is Dt=D2+D3×2>D1. As is obvious from FIGS. 2A and 2B, the thermoelectric module 100 of the present embodiment has a smaller area for arranging the same number of thermoelectric elements 130 than the thermoelectric module of the comparative example has. In other words, the portion 110a of the insulating layer 110 arranged to surround each of the electrodes 112 is spaced apart from the electrode 112, whereby the mounting density of the thermoelectric elements 130 arranged on the substrate 111 can be improved. That is, it is possible to increase the number of thermoelectric elements 130 per unit area while suppressing occurrence of a defect by suppressing displacement of the thermoelectric elements 130 during production or the like, and it can be said that the thermoelectric module 100 of the present embodiment has a structure suitable for improving performance.

Next, a structure of the insulating layer 110 will be described. In the configuration illustrated in FIG. 1, the insulating layer 110 is formed to continuously surround each of the thermoelectric elements 130. This can suppress displacement of the thermoelectric elements 130. As illustrated in FIG. 1, the upper surface of the insulating layer 110 may be arranged at a position closer to the main surface 124 of the substrate 121 than the surface of the thermoelectric element 130 facing the electrode 112 arranged on the substrate 111. Alternatively, for example, the upper surface of the insulating layer 110 may be arranged at the same height as the surface of the thermoelectric element 130 facing the electrode 112 arranged on the substrate 111.

When the upper surface of the insulating layer 110 is arranged closer to the substrate 121 than the surface of the thermoelectric element 130 facing the electrode 112, even if the solder used as the bonding material 113 flows when melted during reflow or the like, movement of the thermoelectric element 130 is suppressed. For example, the upper surface of the insulating layer 110 may be arranged at a position closer to the main surface 124 of the substrate 121 by 2 μm or more than the surface of the thermoelectric element 130 facing the electrode 112. Further, for example, the upper surface of the insulating layer 110 may be arranged at a position closer to the main surface 124 of the substrate 121 by 3 μm or more than the surface of the thermoelectric element 130 facing the electrode 112. Furthermore, for example, the upper surface of the insulating layer 110 may be arranged at a position closer to the main surface 124 of the substrate 121 by 4 μm or more than the surface of the thermoelectric element 130 facing the electrode 112. Even in a case where the upper surface of the insulating layer 110 is at about the same height as the surface of the thermoelectric element 130 facing the electrode 112, the flow of the molten solder is suppressed, and as a result, the displacement of the thermoelectric element 130 is suppressed. On the other hand, when the height of the insulating layer 110 is increased, the insulating layer 110 may interfere with the substrate 121, the electrode 122 arranged on the substrate 121, and the like. Accordingly, the upper surface of the insulating layer 110 is arranged at the same height as the surface of the thermoelectric element 130 facing the electrode 122 arranged on the substrate 121, or at a position closer to the main surface 114 of the substrate 111 than the surface of the thermoelectric element 130 facing the electrode 122 arranged on the substrate 121. The upper surface of the insulating layer 110 may be arranged at a position closer to the main surface 114 of the substrate 111 by, for example, 2 μm or more than the surface of the thermoelectric element 130 facing the electrode 122, or may be arranged at a position closer to the main surface 114 of the substrate 111 by 10 μm or more, or 50 μm or more. For example, the upper surface of the insulating layer 110 may be arranged in a range from the same height as the surface of the thermoelectric element 130 facing the electrode 112 to a portion of the thermoelectric element 130 at a height of ½, ⅓, or ⅕ of the distance between the substrate 111 and the substrate 121. Further, for example, the upper surface of the insulating layer 110 may be arranged at a height in a range of 1 to 100 times the thickness of the bonding material 113 from the surface of the electrode 112, may be arranged at a height in a range of 2 to 20 times the thickness of the bonding material 113, or may be arranged at a height in a range of 3 to 7 times the thickness of the bonding material 113. Here, the descriptions of upper limit values and lower limit values such as “1 to 100 times”, “2 to 20 times”, and “3 to 7 times” are not limited to the described combinations, and can be combined with each other. For example, the description “1 to 100 times” indicates “1 time or more and 100 times or less”. The same applies to upper limit values and lower limit values of numerical ranges in the following description.

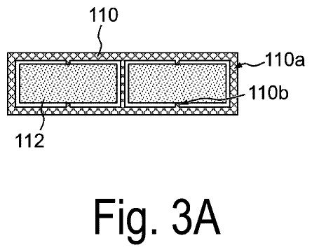

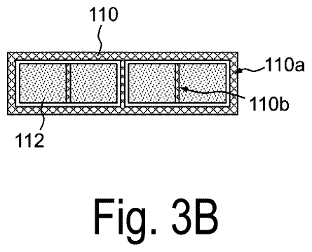

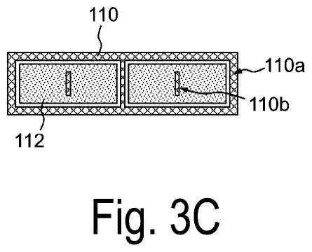

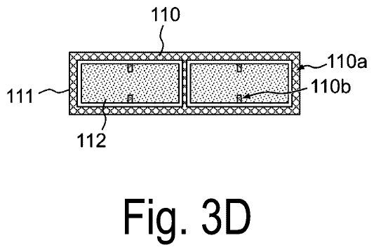

In the configuration illustrated in FIG. 1, the insulating layer 110 is formed to continuously surround each of the thermoelectric elements 130, but the present invention is not limited thereto. The insulating layer 110 may be formed to intermittently surround each of the thermoelectric elements 130. For example, as illustrated in FIG. 3A, the portion 110b of the insulating layer 110 arranged between two thermoelectric elements 130 connected to the same electrode 112 may be divided into two portions that each protrude from the portion 110a of the insulating layer 110 surrounding the electrode 112. In this case, as illustrated in FIG. 3A, the portion 110b of the insulating layer 110 does not need to be arranged on the electrode 112. Alternatively, as illustrated in FIG. 3B, the portion 110b of the insulating layer 110 may be arranged apart from the portion 110a of the insulating layer 110. In the configuration illustrated in FIG. 3B, the portion 110b of the insulating layer 110 is formed to traverse the electrode 112, but may be formed on a part of the electrode 112 as illustrated in FIG. 3C, for example. Alternatively, for example, as illustrated in FIG. 3D, the portion 110b of the insulating layer 110 may be spaced apart from the portion 110a of the insulating layer 110 and may be further composed of two or more portions.

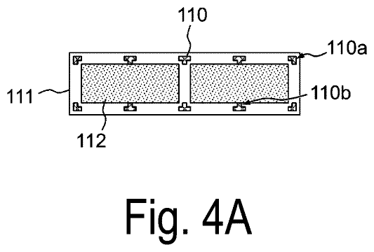

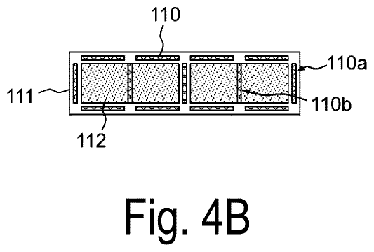

Further, the portion 110a of the insulating layer 110 surrounding the electrode 112 does not need to continuously surround the electrode 112, and may intermittently surround the electrode 112. For example, as illustrated in FIG. 4A, the insulating layer 110 may be arranged to suppress displacement at each corner of the thermoelectric elements 130. Alternatively, for example, as illustrated in FIG. 4B, the insulating layer 110 may be arranged to suppress displacement on each side of the thermoelectric elements 130. In the configuration illustrated in FIG. 4B, a portion of the insulating layer 110 corresponding to each side of the thermoelectric elements 130 is composed of one component, but may be divided into two or more components. Alternatively, for example, the configuration illustrated in FIG. 4A and the configuration illustrated in FIG. 4B may be combined.

In the configurations illustrated in FIGS. 3A to 3D, and FIGS. 4A and 4B, in an orthogonal projection with respect to the main surface 114 of the substrate 111, a portion of the insulating layer 110 arranged to surround one thermoelectric element 130 intermittently surrounds the one thermoelectric element in a rectangular shape. In this case, as illustrated in FIGS. 3A to 3D, and FIGS. 4A and 4B, the insulating layer 110 may be arranged to constitute a part of each of the four sides of the rectangular shape. This makes it possible to effectively suppress the displacement of the thermoelectric element 130. However, the present invention is not limited to this, and the insulating layer 110 is only required to be arranged to form some of the four sides of the rectangular shape. Even when the insulating layer 110 is partially arranged, it is possible to suppress the displacement of the thermoelectric element 130 as compared with a case where the insulating layer 110 is not arranged.

As illustrated on the lower side of FIG. 1, in an orthogonal projection with respect to the main surface 124 of the substrate 111, the shape of the inner edge of the portion of the insulating layer 110 arranged to surround one thermoelectric element 130 may be substantially the same shape as the outer edge of the thermoelectric element 130. In consideration of production variations of the insulating layer 110 and the thermoelectric elements 130, the shape of the inner edge of the portion of the insulating layer 110 arranged to surround one thermoelectric element 130 may be larger than the outer edge of the thermoelectric element 130. However, when the inner edge of the portion of the insulating layer 110 arranged to surround one thermoelectric element 130 becomes large, the mounting density of the thermoelectric elements 130 is reduced. Accordingly, although depending on the size of the thermoelectric element 130, a length between the inner edge of the insulating layer 110 and the outer edge of the thermoelectric element 130 may be, for example, 200 μm or less, further, for example, 100 μm or less, still further, for example, 50 μm or less, or yet further, 20 μm or less. In addition, for example, in the orthogonal projection with respect to the main surface 124 of the substrate 111, in a case where the thermoelectric element 130 has a substantially square shape, the length between the inner edge of the insulating layer 110 and the outer edge of the thermoelectric element 130 may be 20% or less of one side of the square of the thermoelectric element 130. In this case, the length between the inner edge of the insulating layer 110 and the outer edge of the thermoelectric element 130 may be, for example, 10% or less of one side of the square of the thermoelectric element 130, or further, for example, 5% or less, or still further, for example, 2% or less. For example, it is assumed that the thermoelectric element 130 has a size of A [mm²] in the orthogonal projection with respect to the main surface 124 of the substrate 111. In this case, the length between the inner edge of the insulating layer 110 and the outer edge of the thermoelectric element 130 may be 0.2×√A [mm] or less, 0.1×√A [mm] or less, 0.05×√A [mm] or less, or 0.02×√A [mm] or less.

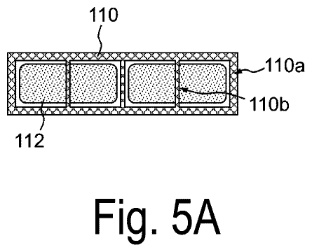

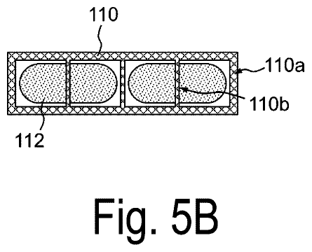

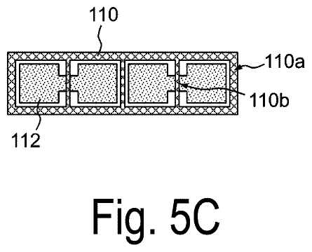

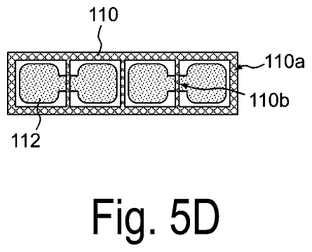

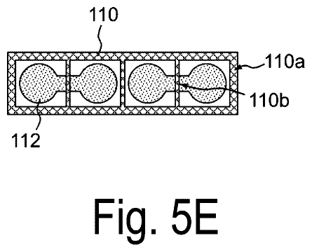

In the configurations illustrated in FIG. 1, FIGS. 3A to 3D, and FIG. 4A, and 4B, the electrodes 112 each are drawn in a rectangular shape, but the shape of each of the electrodes 112 is not limited to a rectangular shape. Examples of the shape of each of the electrodes 112 are illustrated in FIGS. 5A to 5E. The electrodes 112 each may have a shape with four rounded corners as illustrated in FIG. 5A, or may have an arc-shaped end as illustrated in FIG. 5B, for example. In the configuration illustrated in FIG. 5A, all four corners are rounded, but only some of the corners may be rounded. For example, a corner of the electrode 112 may be chamfered in a straight line. The width of a portion arranged between two portions of the electrode 112, to which the thermoelectric elements 130 are bonded, may be narrower than the width of a portion to which each of the thermoelectric elements 130 is bonded. For example, as illustrated in FIG. 5C, the portions to which the thermoelectric elements 130 are bonded may each have a rectangular shape, and the width between the portions may be narrower than the length of one side of the rectangular shape, or as illustrated in FIG. 5D, four corners (or some of the corners) of the rectangular shape of the portion to which each of the thermoelectric elements 130 is bonded may be chamfered. Alternatively, for example, as illustrated in FIG. 5E, the portions to which the thermoelectric elements 130 are bonded may each have a circular shape, and the electrode 112 may have a configuration in which the two circular portions are connected by a portion having a width narrower than the diameter of each of the circles. The shape of the electrode 112 may be appropriately selected depending on the shape of each of the thermoelectric elements 130, bonding strength between the electrode 112 and the thermoelectric elements 130, and the like.

Although an appropriate shape is selected for the shape of the electrode 112, the following consideration may be given to the length between the portion 110a of the insulating layer 110 surrounding the electrode 112 and the outer edge of the electrode 112 in the orthogonal projection with respect to the main surface 124 of the substrate 111. When the length between the portion 110a of the insulating layer 110 and the electrode 112 is increased, the size of the electrode 112 is relatively reduced, and the resistance value of the electrode 112 is increased. As a result, the proportion of power consumed by the electrode 112 may increase, and the performance of the thermoelectric module 100 may be reduced. In addition, the bonding strength between the electrode 112 and the thermoelectric elements 130 may be reduced. On the other hand, when the length between the portion 110a of the insulating layer 110 and the electrode 112 is reduced, the relative size of the electrode 112 is increased, and thus, the trouble of power consumption and the trouble of bonding strength in the electrode 112 are suppressed. However, solder used as the bonding material 113 may leak out beyond a portion where the insulating layer 110 is not arranged during reflow or the like, and a short circuit may occur between adjacent electrodes. In addition, when the length between the portion 110a of the insulating layer 110 and the electrode 112 is reduced, high alignment accuracy is required in a step of forming the insulating layer 110, and thus, the production efficiency may be reduced: for example, it takes time for alignment.

Accordingly, for example, in the orthogonal projection with respect to the main surface 124 of the substrate 111, in a case where the thermoelectric elements 130 each are substantially square, the length between the electrode 112 and a portion of the portion 110a of the insulating layer 110 closest to the electrode 112 may be from 5 to 30% of one side of the square of each of the thermoelectric elements 130. In this case, the length between the electrode 112 and the portion of the portion 110a of the insulating layer 110 closest to the electrode 112 may be, for example, 7% or more of one side of the square of each of the thermoelectric elements 130, further, for example, 10% or more, or still further, for example, 15% or more. On the other hand, the length between the electrode 112 and the portion of the portion 110a of the insulating layer 110 closest to the electrode 112 may be, for example, 25% or less of one side of the square of each of the thermoelectric elements 130, further, for example, 20% or less, or still further, for example, 18% or less. For example, it is assumed that the thermoelectric elements 130 each have a size of A [mm²] in the orthogonal projection with respect to the main surface 124 of the substrate 111. In this case, the length between the electrode 112 and the portion of the portion 110a of the insulating layer 110 closest to the electrode 112 may be from 0.05×√A to 0.3×√A [mm], for example, from 0.07×√A to 0.25×√A [mm], further, for example, from 0.1×√A to 0.2×√A [mm], or still further, for example, from 0.15×√A to 0.18×√A [mm]. Furthermore, for example, although depending on the size of each of the thermoelectric elements 130, the length between the electrode 112 and the portion of the portion 110a of the insulating layer 110 closest to the electrode 112 may be, for example, 50 μm or more, further, for example, 75 μm or more, still further, for example, 100 μm or more, or yet further, for example, 150 μm or more. On the other hand, the length between the electrode 112 and the portion of the portion 110a of the insulating layer 110 closest to the electrode 112 may be, for example, 300 μm or less, further, for example, 250 μm or less, still further, for example, 200 μm or less, or yet further, for example, 180 μm or less. This can suppress leakage of the solder and a decrease in production efficiency while suppressing an increase in resistance value of the electrode 112.

Here, as illustrated on the lower side of FIG. 1, the electrode 112 can be formed smaller than each of the thermoelectric elements 130 in the orthogonal projection with respect to the main surface 124 of the substrate 111. As described above, when the electrode 112 is reduced in size, the resistance value in the electrode 112 increases, and the performance of the thermoelectric module 100 may deteriorate or the bonding strength between the electrode 112 and the thermoelectric elements 130 may decrease. On the other hand, when the electrode 112 is increased in size, the solder used as the bonding material 113 may leak out during reflow or the like, and a short circuit may occur between adjacent electrodes. Accordingly, in a case where the thermoelectric elements 130 each have a size of A [mm²] in the orthogonal projection with respect to the main surface 124 of the substrate 111, the size (area) of the electrode 112 may be, for example, 0.5×A to 0.9×A [mm²] in the orthogonal projection with respect to the main surface 124 of the substrate 111. Further, for example, the size (area) of the electrode 112 may be 0.64×A to 0.81×A [mm²], or further, for example, 0.67×A to 0.72×A [mm²]. This makes it possible to suppress the occurrence of a defect such as a short circuit between electrodes while suppressing an increase in resistance value and a decrease in bonding strength between the electrode 112 and the thermoelectric elements 130.

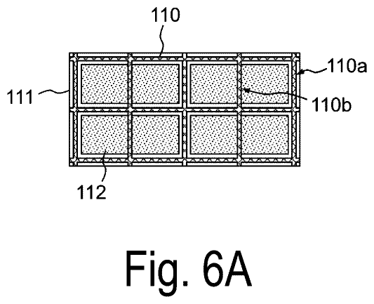

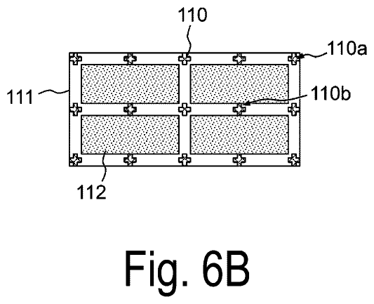

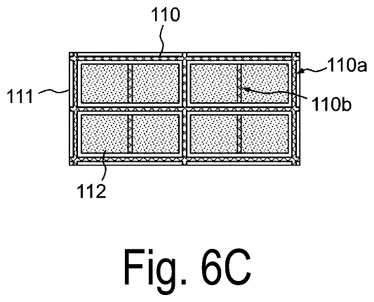

In the configurations illustrated in FIGS. 3A to 3D and FIGS. 4A and 4B, arrangement examples of the insulating layer 110 for two electrodes 112 are illustrated, but the insulating layer 110 can be arranged for more electrodes 112. FIG. 6A illustrates an arrangement example of the insulating layer 110 in a case where the insulating layer 110 continuously surrounds each of the thermoelectric elements 130 and additional electrodes 112 are arranged in the up-down direction and the left-right direction of the drawing. FIG. 6B illustrates an arrangement example of the insulating layer 110 in a case where additional electrodes 112 are arranged in the up-down direction and the left-right direction in the drawing for the configuration illustrated in FIG. 4A, and FIG. 6C illustrates an arrangement example of the insulating layer 110 in a case where additional electrodes 112 are arranged in the up-down direction and the left-right direction in the drawing for the configuration illustrated in FIG. 3B. In other configurations, the insulating layer 110 can be appropriately arranged even when additional electrodes 112 are arranged in the up-down direction and the left-right direction in the drawing. The shape of the electrode 112 is not limited to a rectangular shape, and for example, shapes as illustrated in FIGS. 5A to 5E can be used.

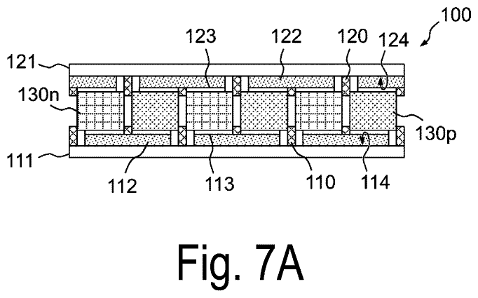

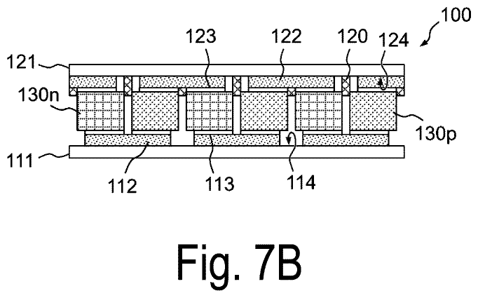

The insulating layer 110 is not limited to be arranged only on the main surface 114 of the substrate 111. As illustrated in FIG. 7A, an insulating layer 120 may be arranged on the main surface 124 of the substrate 121 arranged to face the main surface 114 of the substrate 111. Alternatively, as illustrated in FIG. 7B, the insulating layer 110 need not be arranged on the main surface 114 of the substrate 111, and the insulating layer 120 may be arranged on the main surface 124 of the substrate 121. For example, in the production process of the thermoelectric module 100, the insulating layer is only required to be arranged on a substrate including the electrode to which the thermoelectric elements 130 are connected first, of the substrate 111 and the substrate 121. This can suppress the displacement of the thermoelectric elements 130. For example, the insulating layer 120 arranged on the main surface 124 of the substrate 121 includes a portion arranged to surround each electrode 122 and to be spaced apart from the electrode 122, and a portion arranged between two thermoelectric elements 130 connected to one electrode 122. Additional configurations of the insulating layer 120 can be the same as the various configurations of the insulating layer 110 described above. Thus, the description of the insulating layer 120 is omitted.

Hereinafter, materials of the respective components of the thermoelectric module 100 will be described.

The substrate 111 and the substrate 121 each may be an insulating substrate. For example, a plastic film may be employed for the substrate 111 and the substrate 121. As the plastic film, a polyimide film, a polyamide film, a polyetherimide film, a polyaramid film, a polyamide-imide film, a glass epoxy sheet, or the like may be used. As the substrate 111 and the substrate 121, a substrate of the same material or substrates of different materials may be used. A thickness of the substrate 111 and the substrate 121 may be from 1 to 1000 μm or less, for example, from 10 to 500 μm, or further, for example, from 20 to 100 μm. The material to be used for the substrate 111 and the substrate 121 is not limited to plastic. For example, ceramics such as alumina or aluminum nitride may be employed for the substrate 111 and the substrate 121. For example, an electrically conductive material covered with an insulating layer, such as an aluminum substrate having a surface formed with an alumina layer may be employed for the substrate 111 and the substrate 121.

In the thermoelectric module 100, the thermoelectric elements 130 may be arranged between the substrate 111 and the substrate 121 in such a manner that an N-type thermoelectric element 130n and a P-type thermoelectric element 130p are electrically connected in series. As illustrated on the upper side of FIG. 1, the thermoelectric elements 130n and 130p are not necessarily arranged alternately, and may be arranged in an appropriate order according to the configuration of the electrodes 112 and 122 arranged on the substrate 111 and the substrate 121. Each of the thermoelectric elements 130 may be formed of various types of thermoelectric materials including bismuth-tellurium-based, telluride-based, antimony-tellurium-based, zinc-antimony-based, silicon-germanium-based, bismuth selenide-based, silicide-based, skutterudite-based, oxide-based, and sulfide-based thermoelectric materials. A thickness of the thermoelectric element 130 in a direction sandwiched between the substrate 111 and the substrate 121 may be, for example, from 10 to 1000 μm, further, for example, from 20 to 500 μm, still further, for example, 50 to 200 μm, or yet further from 80 to 120 μm or less.

For example, a material including gold, silver, copper, molybdenum, nickel, aluminum, rhodium, platinum, chromium, palladium, tungsten, or stainless steel, or an alloy thereof may be used for the electrodes 112 and 122. In addition to the metal material, a paste material containing solvents and resin components may also be used for forming the electrodes 112 and 122. When the paste material is used, the solvent, the resin component, or the like may be removed by firing or the like. For example, silver paste or aluminum paste may be employed for the paste material.

Examples of methods for forming the electrodes 112 and 122 include a method for processing the electrode pattern into a predetermined pattern shape, for example, by a well-known physical treatment or chemical treatment based on photolithography or by using such treatments in combination, or a method for forming a pattern of each of the electrodes through screen printing, stencil printing, inkjet printing, or the like. Examples of methods for forming an electrode before patterning include vacuum film formation methods including a physical vapor deposition (PVD) method such as a vacuum vapor deposition method, a sputtering method, and an ion plating method, or a chemical vapor deposition (CVD) method such as thermal CVD and atomic layer deposition (ALD), or a wet process such as various types of coating methods including a dip coating method, a spin coating method, a spray coating method, a gravure coating method, a die coating method, or a doctor blade method, and an electrodeposition method, as well as a silver salt method, an electrolytic plating method, an electroless plating method, and lamination of metal foils. Such methods are appropriately selected according to the metal material. In a case where ceramics such as alumina or aluminum nitride is used for the substrates 111 and 121, the electrodes 112 and 122 may be formed by using a DBC method, an AMB method, or the like.

The electrodes 112 and 122 are required to have high electrical conductivity. High electrical conductivity can be easily achieved in electrodes in which a film is formed by a plating method or a vacuum film formation method, and thus, the electrodes 112 and 122 may be formed by using vacuum film formation methods such as a vacuum vapor deposition method and a sputtering method, an electrolytic plating method, and an electroless plating method. The electrodes 112 and 122 can be easily formed through a hard mask such as a metal mask depending on the dimensions of the electrodes 112 and 122 to be formed and the required dimensional accuracy. Furthermore, in a case where a film is formed by a vacuum film formation method, in order to, for example, improve adhesion with the substrates 111 and 121 to be used and remove moisture, the film may be formed while heating the substrates 111 and 121 as long as the heating does not impair the characteristics of the substrates 111 and 121. In a case of forming a film using a plating method, a film may be further formed by an electrolytic plating method on a film formed by an electroless plating method.

A thickness of each of the electrodes 112 and 122 may be, for example, from 0.01 to 200 μm, further, for example, from 1 to 100 μm, or still further, for example, from 10 to 50 μm. The thickness of each of the electrodes 112 and 122 may be appropriately set in accordance with a resistance value and the like required for the electrodes 112 and 122.

As the bonding materials 113 and 123 for bonding the thermoelectric elements 130 onto the electrodes 112 and 122, for example, a solder material such as cream solder can be used. The cream solder can be applied onto the electrodes 112 and 122 with high accuracy and in a short time by, for example, screen printing using a stencil plate. Examples of the solder material include known materials such as Sn, Sn/Pb alloys, Sn/Ag alloys, Sn/Cu alloys, Sn/Ag/Cu alloys, Sn/Sb alloys, Sn/In alloys, Sn/Zn alloys, Sn/In/Bi alloys, Sn/In/Bi/Zn alloys, Sn/Bi/Pb/Cd alloys, Sn/Bi/Pb alloys, Sn/Bi/Cd alloys, Bi/Pb alloys, Sn/Bi/Zn alloys, Sn/Bi alloys, Sn/Bi/Pb alloys, Sn/Pb/Cd alloys, and Sn/Cd alloys. A thickness of each of the bonding materials 113 and 123 may be, for example, from 2 to 20 μm, further, for example, from 5 to 15 μm, or still further, for example, from 7 to 12 μm after a reflow step of bonding the thermoelectric elements 130 to the electrodes 112 and 122. A thickness at which a large number of bonding points between the electrodes 112 and 122 and the thermoelectric elements 130 are stably formed may be appropriately selected.

Although not illustrated in FIG. 1, FIGS. 7A and 7B, or the like, a solder receiving layer may be arranged between the bonding materials 113 and 123 and the thermoelectric elements 130. The solder receiving layer has a function of improving a bonding performance between the thermoelectric elements 130 and the bonding materials 113 and 123, and is directly bonded to the thermoelectric elements 130. The solder receiving layer may include a metal material. The metal material may be at least one type selected from the group consisting of gold, silver, nickel, aluminum, rhodium, platinum, chromium, palladium, tin, and alloys containing any one of such metal materials. Among such metal materials, the metal material may be gold, silver, nickel, aluminum, or a two-layer structure of tin and gold. From the viewpoints of material cost, high thermal conductivity, and bonding stability, silver, nickel, and aluminum are more suitable as the solder receiving layer.

A thickness of the solder receiving layer may be, for example, from 0.01 to 10 μm or less, further, for example, from 0.05 to 8 μm, still further, for example, from 0.2 to 4 μm, or, yet further, from 0.5 to 3 μm. When the thickness of the solder receiving layer is in such a range, adhesion with the surface of the thermoelectric elements 130 and adhesion with the bonding materials 113 and 123 are excellent, and a bonding with high reliability can be obtained. In addition, not only electrical conductivity but also thermal conductivity can be maintained at a high level, and thus, as a result, the thermoelectric performance as the thermoelectric module 100 is not deteriorated and is maintained. The solder receiving layer may be used as a single layer by depositing a metal material as it is, or may be used as a multilayer by laminating two or more metal materials.

The solder receiving layer may be formed using the above-described metal materials. From the perspective of maintaining thermoelectric performance, the solder receiving layer is required to exhibit high electrical conductivity and high thermal conductivity. Therefore, a film of the solder receiving layer may be formed by using the above-described electrolytic plating method, electroless plating method, or vacuum film formation method.

The material of each of the insulating layers 110 and 120 is not particularly limited, but may be a solder resist from the viewpoint of suppressing wetting and spreading of the solder material to be used as the bonding materials 113 and 123. As the solder resist, for example, an acrylic resin, an epoxy resin, a urethane resin, a polyimide resin, or the like can be used. Among these, from the viewpoint of heat resistance, an epoxy resin or a polyimide resin may be used as the material of the insulating layers 110 and 120.

Examples of methods for forming the insulating layers 110 and 120 include a method for processing a predetermined pattern shape, for example, by a well-known physical treatment or chemical treatment based on photolithography or by using such treatments in combination, and examples of methods for forming the insulating layer 110 include a method for forming a pattern of the insulating layer 110 directly through screen printing, stencil printing, inkjet printing, or the like. Here, the insulating layers 110 and 120 may be layers each having a surface resistivity of, for example, 1.0×10¹¹ Ω/m² or more from the viewpoint of insulation properties. In addition, for example, the insulating layers 110 and 120 each may have a contact angle with respect to water of 60° or more from the viewpoint of suppressing wetting and spreading of the solder material or the like. Further, the insulating layers 110 and 120 may be layers each having a contact angle with respect to water of 60 to 90°. For example, the insulating layers 110 and 120 each may have a contact angle with respect to water of 70 to 80°.

A height of each of the insulating layers 110 and 120 is only required to be appropriately adjusted within the range of the above-described configuration depending on the thickness of each of the thermoelectric elements 130, the thickness of each of the bonding materials 113 and 123 (for example, the solder material (and the solder receiving layer)), the thickness of each of the electrodes 112 and 122, the length between the main surface 114 of the substrate 111 and the main surface 124 of the substrate 121, and the like. The thickness of the portion of the insulating layer 110 or 120 arranged on the main surface 114 or 124 of the substrate 111 or 121 and the thickness of the portion of the insulating layer 110 or 120 arranged on the electrode 112 or 122 may be different from each other or may be the same. For example, in a case where a solder resist is uniformly applied as a material of the insulating layers 110 and 120 on the main surfaces 114 and 124 of the substrates 111 and 121 and portions where the thermoelectric elements 130 are arranged are opened using a lithography method or the like, the thickness of each of the portions of the insulating layers 110 and 120 arranged on the main surfaces 114 and 124 of the substrates 111 and 121 and the thickness of each of the portions arranged on the electrodes 112 and 122 can be different thicknesses. On the other hand, in this case, the height of each of the portions of the insulating layers 110 and 120 arranged on the main surfaces 114 and 124 of the substrates 111 and 121 and the height of each of the portions of the insulating layers 110 and 120 arranged on the electrodes 112 and 122 from the main surfaces 114 and 124 of the substrates 111 and 121 can be equal to each other. In addition, in a case where the pattern of the insulating layer 110 is directly formed using a screen printing method or the like, the thickness of each of the portions of the insulating layers 110 and 120 arranged on the main surfaces 114 and 124 of the substrates 111 and 121 and the thickness of each of the portions of the insulating layers 110 and 120 arranged on the electrodes 112 and 122 can be equal to each other.

As described above, the thermoelectric module 100 of the present embodiment includes the insulating layer 110 (insulating layer 120) formed to surround each of the thermoelectric elements 130. This can suppress the displacement of the thermoelectric elements 130, and thus can suppress a defect such as the occurrence of a short circuit, and can improve, for example, a production yield of the thermoelectric module 100. The portion 110a of the insulating layer 110 (insulating layer 120) surrounding each of the electrodes 112 (electrodes 122) is arranged apart from the electrode 112 (electrode 122). This can improve the mounting density of the thermoelectric elements 130. That is, it can be said that the thermoelectric module 100 of the present embodiment has a configuration suitable for improving the performance of the thermoelectric module.

The invention is not limited to the foregoing embodiments, and various variations/changes are possible within the spirit of the invention.

What is claimed is

1. A thermoelectric module comprising:
a first substrate having a first main surface;
a second substrate having a second main surface arranged so as to face the first main surface;
a plurality of thermoelectric elements arranged between the first main surface and the second main surface; and
an electrode arranged on the first main surface and connected to a first thermoelectric element and a second thermoelectric element among the plurality of thermoelectric elements, wherein
an insulating layer including a first portion and a second portion is arranged on the first main surface, the first portion being arranged to surround the electrode and to be spaced apart from the electrode, the second portion being arranged between the first thermoelectric element and the second thermoelectric element.

2. The thermoelectric module according to claim 1, wherein the insulating layer is formed to continuously or intermittently surround each of the first thermoelectric element and the second thermoelectric element.

3. The thermoelectric module according to claim 2, wherein in an orthogonal projection with respect to the first main surface, a portion of the insulating layer arranged so as to surround the first thermoelectric element is arranged to intermittently surround the first thermoelectric element in a rectangular shape having four sides and constitute a part of each of the four sides of the rectangular shape.

4. The thermoelectric module according to claim 2, wherein, in an orthogonal projection with respect to the first main surface, a shape of an inner edge of a portion of the insulating layer arranged so as to surround the first thermoelectric element is the same as or larger than a shape of an outer edge of the first thermoelectric element.

5. The thermoelectric module according to claim 1, wherein
in an orthogonal projection with respect to the first main surface, each of the plurality of thermoelectric elements has a size of A [mm²], and
a length between the electrode and a portion of the first portion closest to the electrode is 0.05×√A [mm] or more, and 0.3×√A [mm] or less.

6. The thermoelectric module according to claim 1, wherein an upper surface of the insulating layer is arranged at a same height as surfaces of the first thermoelectric element and the second thermoelectric element facing the electrode, or is arranged at a position closer to the second main surface than the surfaces of the first thermoelectric element and the second thermoelectric element facing the electrode.

7. The thermoelectric module according to claim 1, wherein the upper surface of the insulating layer is arranged at a position closer to the second main surface than the surfaces of the first thermoelectric element and the second thermoelectric element facing the electrode by 2 μm or more.

8. The thermoelectric module according to claim 1, wherein the first thermoelectric element and the second thermoelectric element have different conductivity types.

9. The thermoelectric module according to claim 1, further comprising, provided that the electrode is a first electrode and the insulating layer is a first insulating layer, a second electrode arranged on the second main surface and connected to the first thermoelectric element and a third thermoelectric element among the plurality of thermoelectric elements, wherein
a second insulating layer including a third portion and a fourth portion is arranged on the second main surface, the third portion being arranged to surround the second electrode and to be spaced apart from the second electrode, the fourth portion being arranged between the first thermoelectric element and the third thermoelectric element.

10. The thermoelectric module according to claim 1, wherein the second portion is not arranged on the electrode.

11. The thermoelectric module according to claim 1, wherein the second portion is arranged apart from the first portion.
